(19) United States
(12) Patent Application Publication
(10) Pub. No.: US 2003/0020111 A1
(43) Pub. Date: Jan. 30, 2003

(54) Economic and low thermal budget spacer nitride process

(76) Inventor: Malcolm J. Bevan, Dallas, TX (US)

Correspondence Address: TEXAS INSTRUMENTS INCORPORATED, P O BOX 655474, M/S 3999, DALLAS, TX, 75265

(21) Appl. No.: 10/193,332

(22) Filed: Jul. 11, 2002

Related U.S. Application Data
(60) Provisional application No. 60/305,142, filed on Jul. 16, 2001.

(51) Int. Cl. H01L 21/336

(52) U.S. Cl. 257/303; 438/303

(57) ABSTRACT

An economic and low thermal budget spacer is provided for both the cap oxide and nitride spacer is provided by amido-based silicon precursors such as BTBAS with an oxide to form the cap oxide and with same precursor and ammonia to form the nitride in a single wafer process.

### FIELD OF INVENTION

This invention relates to Metal Oxide Semiconductor (MOS) transistors and more particularly to economic and low thermal budget process for the nitride spacer.

### BACKGROUND OF INVENTION

A Metal Oxide Semiconductor (MOS) transistor is well known and methods of fabricating MOS transistors is well known. See, for example, book entitled “VLSI Technology, Second Edition” edited by S. M. Sze, McGraw Hill publication and/or U.S. Pat. No. 5,472,887 of Hutter et al. Both NMOS and PMOS are described as well as both high and low voltage transistors. This patent is incorporated herein by reference. A typical MOS transistor is shown in cross-section in FIG. 1. It includes a silicon base with a polysilicon gate on top of the substrate with a dielectric oxide between the gate and the base. In the processing steps, for example, the PMOS regions are covered with photoresist and a phosphorus implant to the NMOS regions to provide an N⁺ poly implant at the NMOS gates. This is not shown. A resist is placed over the gate regions and etched to form the gates with the NMOS gates having N⁺ poly and PMOS having undoped poly. A layer of about 50 Angstroms of polysilicon oxide covers the top of the NMOS and PMOS silicon base. An N LDD implant of the NMOS regions is performed with the PMOS regions covered with resist. A cap oxide of ˜150 Angstroms is deposited over the gates and the transistor regions as described in more detail in the background. A PLDD implant is performed on the PMOS regions while the NMOS regions is covered with the resist. After the PLDD implant a silicon nitride Si₃N₄ layer of about 500-1000 Angstroms is formed over the structure to form after an etch side wall spacer on either side of the gates with the cap oxide. This forms sidewalls extending from the sides of the gates. The further source/drain implant is performed with appropriate resists. The sidewalls screen these later implants from the gates to provide stepped implants or lighter-doped extensions to source and drain as illustrated in FIG. 1.

The present invention relates to providing this cap oxide covering and then silicon nitride layer. A patterned etch is applied over the configuration leaving the side wall spacer of silicon nitride and the cap oxide as shown in FIG. 1. There are variations on these approaches—L-offset spacer; disposable spacers; or silicide contact spacers and all require combinations of oxide and nitride films.

In the conventional batch process for the placement of the cap oxide the precursor is often TEOS (Tetraethyloxysilicate) reacting with oxygen when heated in a furnace for three hours at 650 degrees C. The silicon nitride is formed in a separate furnace with Dichlorosilane (DCS) with added ammonia (NH₃) for three to four hours at 750 degrees C. In a batch processing they stack the wafers in a vertical furnace and can process about 150 wafers at a time.

FIG. 2 illustrates the vertical furnace in the batch process with a quartz or silicon carbide boat containing the wafers. The boat sits on a rotating pedestal and DCS and NH₃ are applied at one end and pass about the boat and out to a vacuum. Side dummies or additional wafers are placed at either end of the boat to ensure constant thermal mass and reproducible gas flows. See FIG. 3. There is 6 lots of 24 wafers. If not all 6 lots are available, it is necessary to fill rest of the empty slots with filler wafers. Filler or side dummies can only be used a limited number of times before the nitride needs to be stripped off because the nitride under stress and is too thick it starts shedding and gives off particles. The use of filler wafers for the nitride process can only be used four to six times (6000Angstroms of deposited nitride) and reworked a limited number of times (typically four) before they need to be scrapped (stress-induced slip and breaks).

Chlorinated precursors like DCS give the byproduct NH₄CL which is a further source of particles and there is a need for frequent preventive maintenance as well as complicated exhaust lines. There is a concern with the intentionally added dopants at these temperatures for this time period in that they become deactivated or implanted junctions move. There is also enhanced-diffusion problems (Transient Enhanced Diffusion—TED) such as the Boron diffusing too far under the gate that can only be reduced by minimizing subsequent processing temperatures.

It is therefore desirable to provide a process with improved figure of merit by a lower thermal budget (both temperature and time) and further a process that lowers cost of the process. It is desirable that deposited films are able to be removed by both dry plasma etching and wet chemical etching.

### SUMMARY OF INVENTION

In accordance with one embodiment of the present invention applicant a new non-halogen based silicon source is used rather than the customary Dichlorosilane (DCS) and a single wafer process is used that offers better utilization and does not need wasted filler wafers.

### DESCRIPTION OF DRAWINGS

FIG. 1 illustrates a cross-section of a prior art MOS transistor;

FIG. 2 illustrates a vertical furnace used in batch batch processing;

FIG. 3 illustrates the boat in the vertical furnace if FIG. 2;

FIG. 4 illustrates the single process handler;

FIG. 5 illustrates the method according to the present invention;.

FIG. 6 illustrates the L-shaped side-walls according to one embodiment of the present invention; and

FIG. 7 illustrates the L-shaped side-walls according to a second embodiment of the present invention.

### DESCRIPTION OF PREFERRED EMBODIMENTS OF THE PRESENT INVENTION

In accordance with one embodiment of the present invention a single wafer process is used rather than a batch process. BTBAS (bis t-ButylaminoSilane SiH₂(t-BuNH)₂) is used with oxygen (O₂) or nitrous oxide (N₂O) for the cap oxide over the silicon base and gate oxide and BTBAS is used with ammonia (NH₃) for the nitride. BTBAS allows the process for both the cap oxide and nitride to be done in a single-wafer chamber at a lower temperature. The BTBAS is one example from a family of amido compounds SiHₓ(NR1R2)_{y}(NR3R4)_{4-x-y} such as SiH(N(CH₃)₂)₃; Si(N(CH₃)₂)₄ or Si(N(C₂H₅)₂)₄ where the latter is tetrakisdiethylamidosilane. Unlike the prior are BTBAS is a non-chlorine based silicon source. For that matter it is a non-halogen based silicon source. With a single wafer process according to the preferred embodiment of the present invention the thermal budget for both processes is, for example, 2 minutes at less than 550 degrees C. The range of temperatures can be from 400 to 700 degrees C. at from one to four minutes.

FIG. 4 illustrates the single wafer process in a main frame wafer handler such as Applied Materials TANOX™ with a liquid delivery system (LDS) utilizing liquid flow controllers (LFC) and heated vaporisor of for example ATMI or STEC. TANOX™ has a remote plasma source using NF₃ to volatalise deposits after processing so many wafers such as after 10-20 um accumulated deposit. Alternatively, a thermal NF₃ or ClF₃ in situ clean process can be used. This adds to the cost but is offset by need for regular preventive maintenances with furnaces after at most 10-20 μm-deposition and boat, etc. have to be cleaned etc. and down for 1 to 2 days. A typical wafer handler 11 has up to four nitride or oxide processing chambers so two can be used for oxide(chambers 31 and 33) and two for the nitride process (chambers 33 and 35) to maximize the throughput. There are also two cooling chambers and input/output chambers or loadlocks.

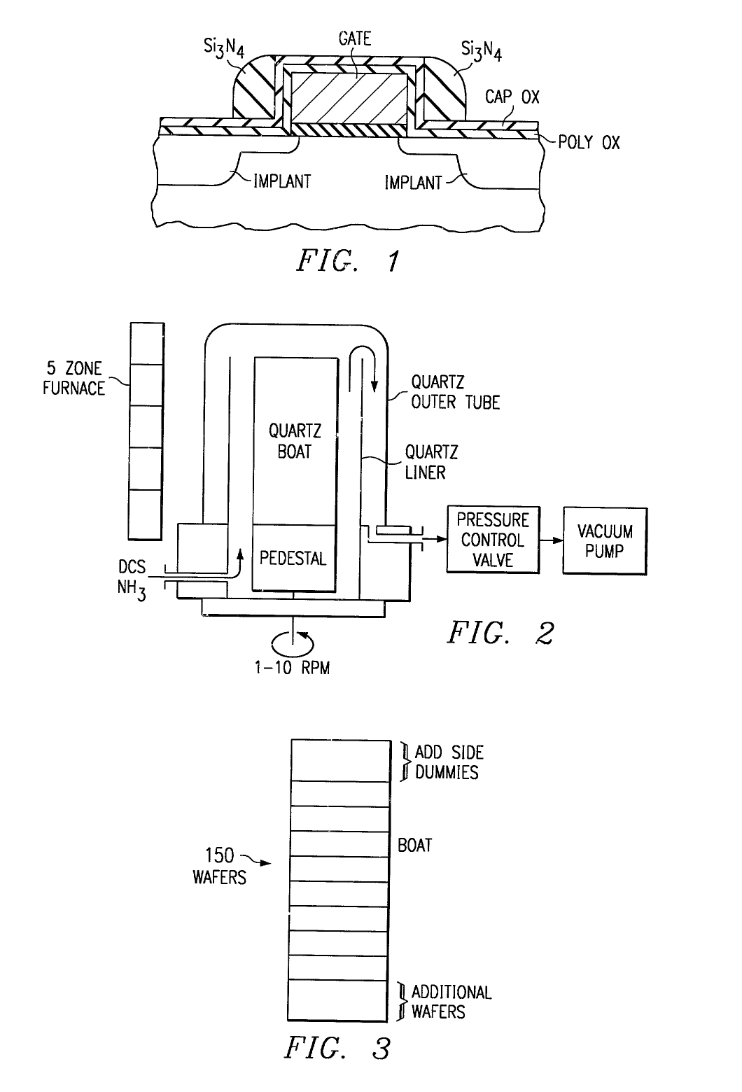

Referring to FIG. 5 there is illustrated the process steps of Step 101 the wafer handler places, for example, a wafer into each of the oxide chambers 31 and 33 in FIG. 4. The next step 102 is the cap oxide step 102 with the BTBAS precursor in the oxygen chambers 31 and 33 for 2 minutes at about 550 degrees C. or less. The next step 103 is moving the wafers out of the cap ox chambers 31 and 33 into the nitride chambers for the nitride processing. The next step 104 is the nitride processing in chambers 33 where BTBAS precursor is reacted with ammonia (NH₃) to form the nitride cover over the cap oxide as illustrated in FIG. 2 at the lower temperatures under about 550 degrees C. In this process one only has to deal with Si₃N₄ or SiO₂. No unwanted NH₄CL is formed.

In accordance with another embodiment of the present invention, the chambers can be used for both the cap oxide step and the nitride step by removing purging out the oxygen and adding the ammonia. The wafer throughput would be hit by the need to purge out oxygen or ammonia and would be preferable to have dedicated chambers for either process. Silicon oxynitride would be possible by adding small levels of N2O with the amido compound and ammonia. Ammonia would be in excess to reflect ease of formation of SiO₂ over Si₃N₄.

A different precursor HCN (hexachlorosilane) can be used with ammonia (NH₃) to operate at the lower temperatures but is a chlorinated precursor that gives the NH₄CL byproduct with particles and the need for preventive maintenance as well as the more complicated exhaust lines.

Precursors like BTBAS are relatively expensive at $5/gm and single wafer process can utilize the precursor more efficiently (greater than 10%) than a batch process (less than 10%). In addition, single wafer process can offer more flexibility in terms of supporting more processes (40 Angstroms to 1000 Angstroms) utilizing tool more efficiently. By the use of a single wafer process, the thermal budget is reduced down to 2 minutes at under 550 degrees C. or less. Also a savings since there are no filler wafers that need to be reworked or constantly replaced.

As lower deposition temperatures are sought, attention has to be given to chemical stoichiometry. Whereas cap oxide grown at 650 degrees C. with TEOS is close to stoichiometric; i.e. SiO₂, its refractive index is approximately 1.44 compared to 1.46 for thermal silicon oxide grown at elevated temperatures above 900 degrees C. This suggests SiO2 is not as dense as thermal oxide. For SiO₂ deposition from amido precursors, it is important to have sufficient oxidant (O₂ or N₂O) to ensure complete oxidation and elimination of alkylamido groups to avoid incorporation of carbon or hydrogen and avoid non-stoichiometric SiO₂. Latter incorporation will affect etching characteristics of cap oxide.

Silicon nitride has tendency to be non-stoichiometric, especially at the lower temperatures and affect its etching characteristics more than with cap oxide. Films can be classed as SiₓN_{y}H_{z} and deviate from Si₃N₄ as seen at greater than 750 degree C. with DCS. Carbon incorporation can be avoided but silicon nitride can be made Si or N-rich with changes in gas phase compositions. The hydrogen content tends to be in the range 5 to 20%. This selectivity can be utilized as Si-rich nitride would expect to etch differently from N-rich nitride (wet or dry etching).

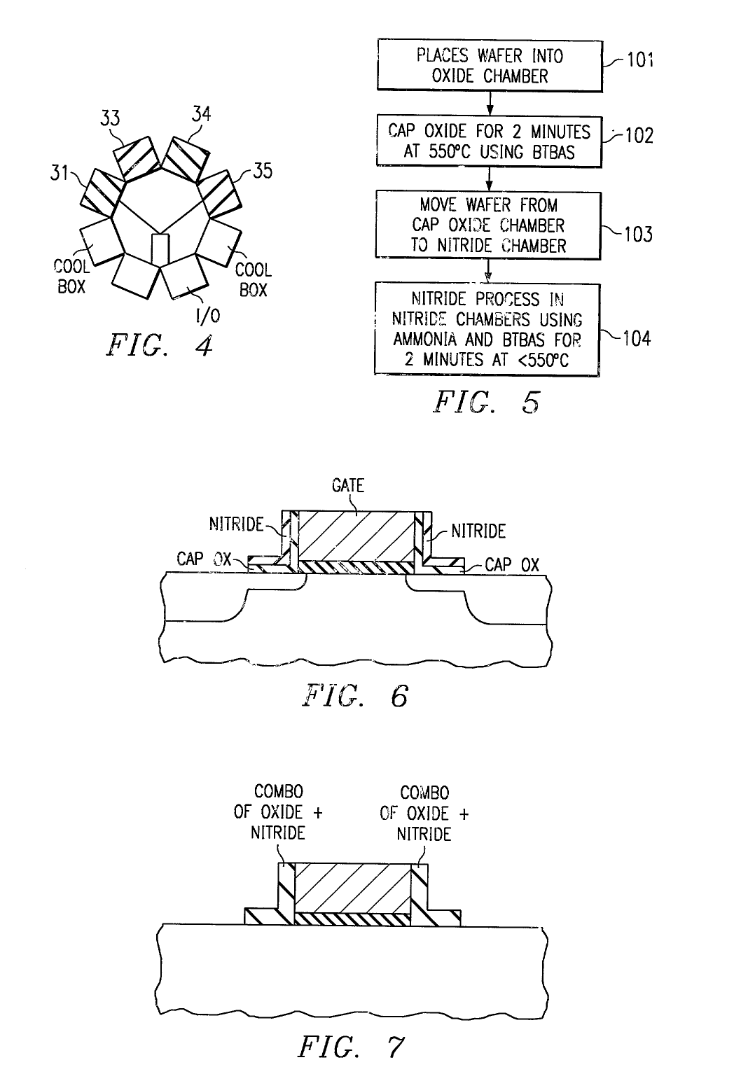

The subject invention may also be used with all types of spacer or offset applications and L-shaped spacer as illustrated in connection with FIG. 6. In an effort to save mask steps the side walls may also be provided by L-shaped spacer formed in either side of the gate by either sequentially 500 Angstrom Cap oxide layer and then an a 300 Angstrom Nitride layer as illustrated in FIG. 6 or an L-Spacer of the combination of oxide and nitride with grades layers of SiO₂ to Si₃N₄ as illustrated in another embodiment as illustrated in FIG. 7. This L-shaped process could be done in while in a single chamber.

In is important that the selection of the precursor that the films need to be etched by both the dry etch and a wet etch. It is is particularly necessary to be able to dry etch the nitride to stop on the cap oxide. Also there is the need to remove them chemically or wet process to make openings for the CMOS contacts, etc. Stoichiometry should be adjusted so nitride can be removed with for example standard etch of hot phosphoric acid.

In the claims:

1. A method of forming a nitride spacer for MOS transistors comprising the steps of:
providing a silicon wafer with polysilicon gate on a silicon base; and
processing a non-halogen based precursor in a single wafer process chamber to form said nitride spacer.

2. The method of claim 1 wherein said precursor is a non-chlorine based precursor.

3. The method of claim 1 wherein said precursor is from a family of amido compounds SiHₓ(NR1R2)_{y}(NR3R4)_{4-x-y}.

4. A method of forming an oxide and nitride spacer for MOS transistors comprising the steps of:
providing a silicon wafer with polysilicon gate on a silicon base; and
processing a non-halogen based precursor in a single wafer process chamber to form said oxide and nitride spacer.

5. The method of claim 4 wherein said precursor is a non-chlorine based precursor.

6. The method of claim 4 wherein said precursor is from a family of amido compounds SiHₓ(NR1R2)_{y}(NR3R4)_{4-x-y}.

7. A method of forming an oxide and nitride mixer spacer for MOS transistors comprising the steps of:
providing a silicon wafer with polysilicon gate on a silicon base; and
processing a non-chlorine based precursor in a single wafer process chamber to form said oxide and nitride combination spacer.

8. The method of claim 7 wherein said precursor is from a family of amido compounds is used with ammonia to form said nitride spacer.

9. The method of claim 7 wherein said precursor is from a family of amido compounds used with oxide to form said cap oxide.

10. The method of claim 4 wherein said precursor is from a family of amido compounds used with oxide to form the cap oxide in a single wafer process before the amido compound is used with ammonia to form the nitride spacer.

11. The method of claim 10 wherein said processing includes heating said wafer in a chamber between 400 and 700 degrees C. for under five minutes to form said nitride spacer.

12. The method of claim 11 wherein said processing includes heating said wafer in a chamber between 400 and 700 degrees C. for under five minutes to form said cap oxide.

13. The method of claim 7 wherein said processing includes heating said wafer in a chamber between 400 and 700 degrees C. for under five minutes.

14. The method of claim 1 wherein said processing includes heating said wafer in a chamber between 400 and 700 degrees C. for under five minutes to form said nitride spacer.

15. The method of claim 1 wherein said precursor is BTBAS.
